(19) United States
(12) Patent Application Publication
(10) Pub. No.: US 2004/0076042 A1
(43) Pub. Date: Apr. 22, 2004

(54) High performance memory column group repair scheme with small area penalty

(76) Inventors: Sifang Wu, Savage, MN (US); Steven M. Peterson, Eagan, MN (US); Kevin R. LeClair, Prior Lake, MN (US)

Correspondence Address: LSI Logic Corporation, Corporate Legal Department, Intellectual Property Services Group, 1551 McCarthy Boulevard, M/S D-106, Milpitas, CA, 95035, US

(21) Appl. No.: 10/272,551

(22) Filed: Oct. 16, 2002

(51) Int. Cl. G11C 29/00

(52) U.S. Cl. 365/200

(57) ABSTRACT

A memory having built-in self repair with column shifting is provided. The total single columns are divided into smaller column groups and a bad column group is repaired with a redundant column group. Each column group is multiplexed into a pair of column group bitlines, which are fed into a shift circuit for the column group and a shift circuit for an adjacent column group. The shift circuit for the column group nearest the redundant column group receives the bitlines for that column group and the redundant column group bitlines. If a bad column group is detected, then starting with the column group furthest from the redundant column group, the shift circuit for each column group before the bad column group is deactivated. The shift circuit for the bad column group and the shift circuit for each column group after the bad column group are activated. Therefore, the bad column group is shifted out of the memory and the redundant column group fills the void.

### BACKGROUND OF THE INVENTION

1. Technical Field

The present invention relates to memory design and, in particular, to built-in self repair. Still more particularly, the present invention provides a method and apparatus for providing built-in self repair with column shifting.

2. Description of the Related Art

A memory circuit is like an electronic checkerboard, with each square holding one bit of data or instruction. Each square, also referred to as a “cell,” has a separate address and can be manipulated independently. Cells are addressed as columns of cells. When manufacturing a memory circuit, or chip, columns may be combined for input/output (I/O) operations. For example, eight columns may be multiplexed (MUXed) together into a single I/O. This is referred to as an 8:1 MUX. Thirty-two columns may be multiplexed together into an I/O, referred to as a 32:1 MUX.

Due to difficulties in manufacturing a memory with a high number of elements, bad columns or groups of columns are likely to occur. After fabrication, a memory chip may be tested to determine whether bad columns or groups of columns exists. However, discarding a memory chip for one bad column is costly. Therefore, memory circuits are designed with built-in self repair (BISR).

In order to achieve memory column built-in self repair, some redundant columns are required to replace the bad columns in the memory itself. One BISR schemes replaces a bad column by using a redundant I/O and its associated columns (32 columns for a 32:1 mux). This technique is referred to as “I/O repair” and is easy to implement. FIG. 1 is a diagram illustrating an example of an I/O repair scheme. The memory circuit includes a plurality (N+1) of groups (I/Os) of thirty-two columns. I/O 0 102, I/O 1 104, and I/O N 106 are shown. The memory circuit has a 32:1 MUX, multiplexing thirty-two single columns to a single data output or input.

The memory circuit in FIG. 1 also includes redundant I/O 108 for repairing a bad I/O. In this case, the redundant memory consists of a total of thirty-two columns. Thus, an I/O is a group of column groups with each column group including eight columns. MUX and buffer 112 may be selectively controlled to provide access to I/O 0 102 or redundant I/O 108. Similarly, MUX and buffer 114 may be selectively controlled to provide access to I/O 1 104 or redundant I/O 108 and MUX and buffer 116 may be selectively controlled to provide access to I/O N 106 or redundant I/O 108.

In the example shown in FIG. 1, I/O 1 104 has bad columns. Therefore, MUX and buffer 114 may be selected to provide access to the redundant I/O rather than I/O 1. This may be done after fabrication, such as by burning a fuse. Alternatively, the columns may be tested and control signals may be set for the multiplexors at system start-up.

The I/O repair scheme shown in FIG. 1 has several disadvantages. First, the area penalty for the redundant columns may become very large for high column multiplexing. For example, a 32:1 MUX multiplexes thirty-two columns into a single I/O bit. For a memory with ten I/O bits and a 32:1 MUX, there would be three hundred twenty columns and thirty-two redundant columns for a 10% area penalty. Furthermore, there is a significant performance penalty, because the redundant I/O has to be multiplexed with all regular I/O. The long wire 120 through the entire I/O width has a very large capacitance. Furthermore, an additional multiplex and buffer state must be added to the critical path.

Next, with reference to FIG. 2, a single column repair scheme is illustrated. The memory circuit includes a plurality (N+1) of groups of thirty-two columns. I/O 0 202, I/O 1 204, and I/O N 206 are shown. Each I/O includes single redundant columns 212, 214, 216 that may be multiplexed into the I/O. This repair scheme is more difficult to implement because it requires a control circuit for each single column to decide whether or not to repair the single column. In addition, the layout of the circuit is difficult to fit into the narrow single column pitch. Therefore, a lot of extra area needs to be added to the column MUX area in addition to the redundant columns.

Therefore, it would be advantageous to provide an improved method and apparatus for built-in self repair of columns in a memory circuit.

### SUMMARY OF THE INVENTION

The present invention provides a built-in self repair with column shifting for memory circuits. The columns in the memory are divided into smaller column groups and a bad column group is repaired with a redundant column group. Each column group is multiplexed into a pair of column group bitlines, which are fed into a shift circuit for the column group and a shift circuit for an adjacent column group. The shift circuit for the column group nearest the redundant column group receives the bitlines for that column group and the redundant column group bitlines. If a bad column group is detected, then starting with the column group furthest from the redundant column group, the shift circuit for each column group before the bad column group is deactivated. The shift circuit for the bad column group and the shift circuit for each column group after the bad column group are activated. Therefore, the bad column group is shifted out of the memory and the redundant column group fills the void.

### BRIEF DESCRIPTION OF THE DRAWINGS

The novel features believed characteristic of the invention are set forth in the appended claims. The invention itself however, as well as a preferred mode of use, further objects and advantages thereof, will best be understood by reference to the following detailed description of an illustrative embodiment when read in conjunction with the accompanying drawings, wherein:

FIG. 1 is a diagram illustrating an example of an I/O repair scheme;

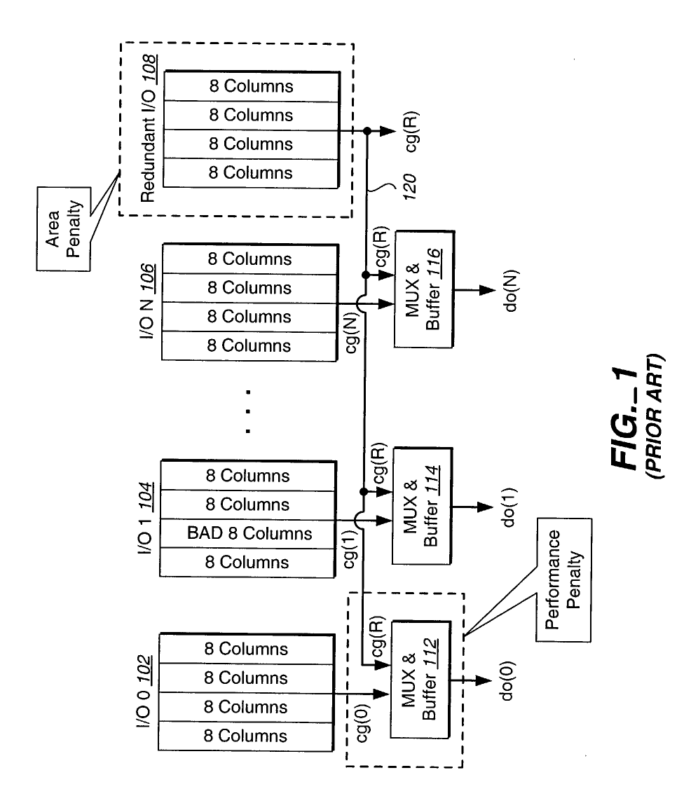

FIG. 2 illustrates a single column repair scheme;

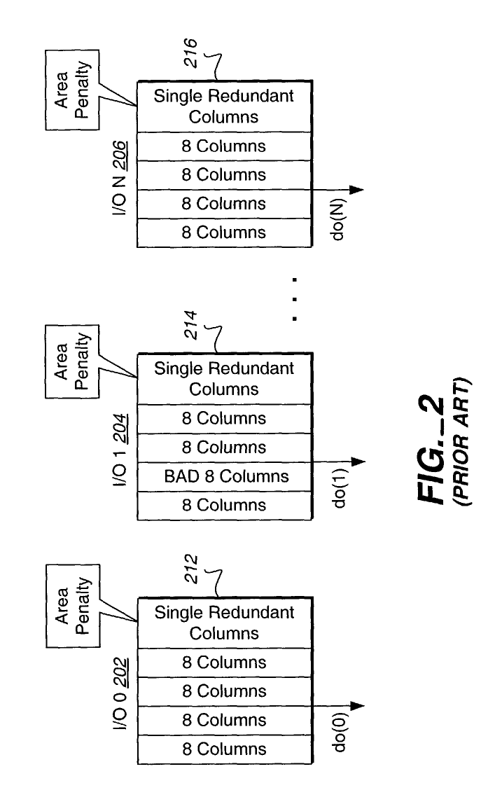

FIG. 3 is an example diagram illustrating a column group repair scheme with column shifting in accordance with a preferred embodiment of the present invention;

FIG. 4 is a diagram illustrating an example column group repair by shifting out a bad column group in accordance with a preferred embodiment of the present invention;

FIG. 5 is an example diagram illustrating a column shifting column group repair scheme with 8:1 MUX in accordance with a preferred embodiment of the present invention;

FIG. 6 is a block diagram illustrating a memory with column shifting column group repair in accordance with a preferred embodiment of the present invention;

FIG. 7 is a circuit diagram of an example shift circuit in accordance with a preferred embodiment of the present invention; and

FIG. 8 is a flowchart of the operation of a column shifting repair scheme in accordance with a preferred operation of the present invention.

### DETAILED DESCRIPTION

The description of the preferred embodiment of the present invention has been presented for purposes of illustration and description, but is not intended to be exhaustive or limited to the invention in the form disclosed. Many modifications and variations will be apparent to those of ordinary skill in the art. The embodiment was chosen and described in order to best explain the principles of the invention the practical application to enable others of ordinary skill in the art to understand the invention for various embodiments with various modifications as are suited to the particular use contemplated.

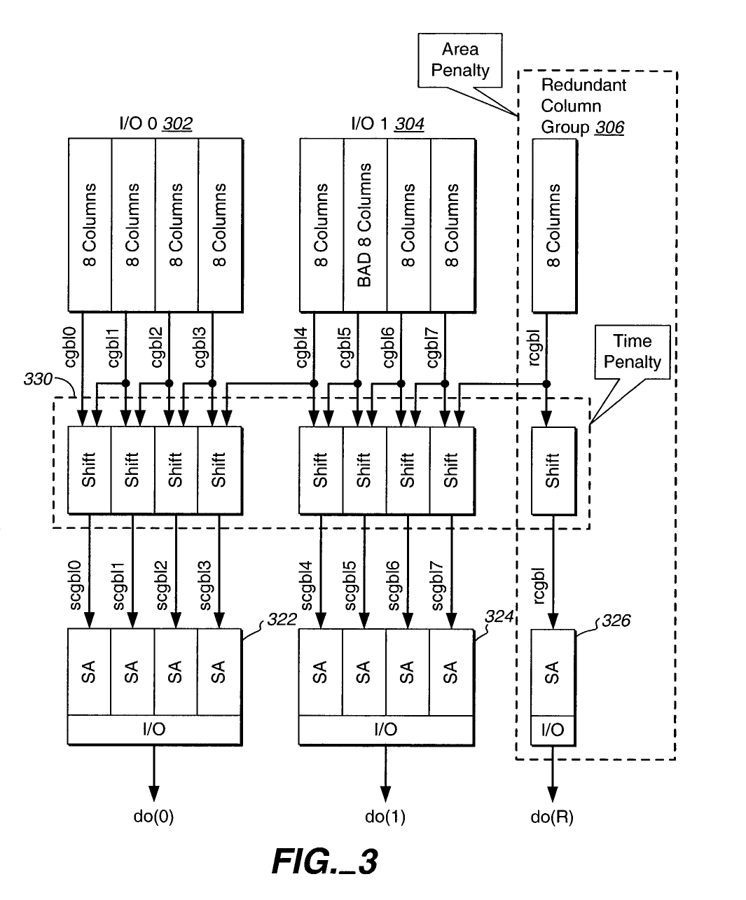

With reference now to the figures and in particular with reference to FIG. 3, an example diagram illustrating a column group repair scheme with column shifting is shown in accordance with a preferred embodiment of the present invention. The memory circuit includes a plurality (N+1) of groups of thirty-two columns. I/O 0 302 and I/O 1 304 are shown. For simplicity, only two I/Os are shown and the columns are divided into groups of eight columns. However, the memory may include more or fewer I/Os and may divide the columns into more or fewer columns depending upon the implementation.

In this example, the first stage has eight single columns with eight pairs of bitlines multiplexed into one column group with one pair of column group bitlines. For example, I/O 0 302 has four groups of eight columns multiplexed into column group bitlines cgbl0, cgbl1, cgbl2, cgbl3. Similarly, I/O 1 304 has four groups of eight columns multiplexed into column group bitlines cgbl4, cgbl5, cgbl6, cgbl7. The memory also includes redundant column group 306, which is one group of eight columns multiplexed into redundant column group bitlines rcgbl.

In accordance with a preferred embodiment of the present invention, the memory includes shifting stage 330 including a shift circuit for each column group. Each pair of column group bitlines is fed into a shift circuit for the column group and a shift circuit for an adjacent column group. When the memory is tested and a bad column group is identified, the shift circuits for the bad column group and each column group after the bad column group are activated. Thus, the bad column group is shifted out and redundant column group 306 is shifted in at the end.

In a third stage, each pair of shifted column group bitlines is fed into a sense amplifier and the four sense amplifier outputs for each I/O are then multiplexed into a I/O. In the example shown in FIG. 3, the shifted column group bitlines for I/O 0 are fed into sense amplifiers 322 and the outputs of sense amplifiers 322 are multiplexed into data output do(0). Similarly, the shifted column group bitlines for I/O 1 are fed into sense amplifiers 324 and the outputs of sense amplifiers 324 are multiplexed into data output do(1). The redundant column group bitlines from the shifting stage may also be fed into sense amplifier 326 and accessed as do(R).

The column group repair scheme with column shifting of the present invention has a small area penalty, since only a small redundant column group of, for example, eight columns is provided rather than an entire I/O. The column shifting repair scheme has a minor time penalty due to shifting stage 330; however, the design is simplified and the area penalty is significantly reduced while still providing an effective repair scheme for a bad column group.

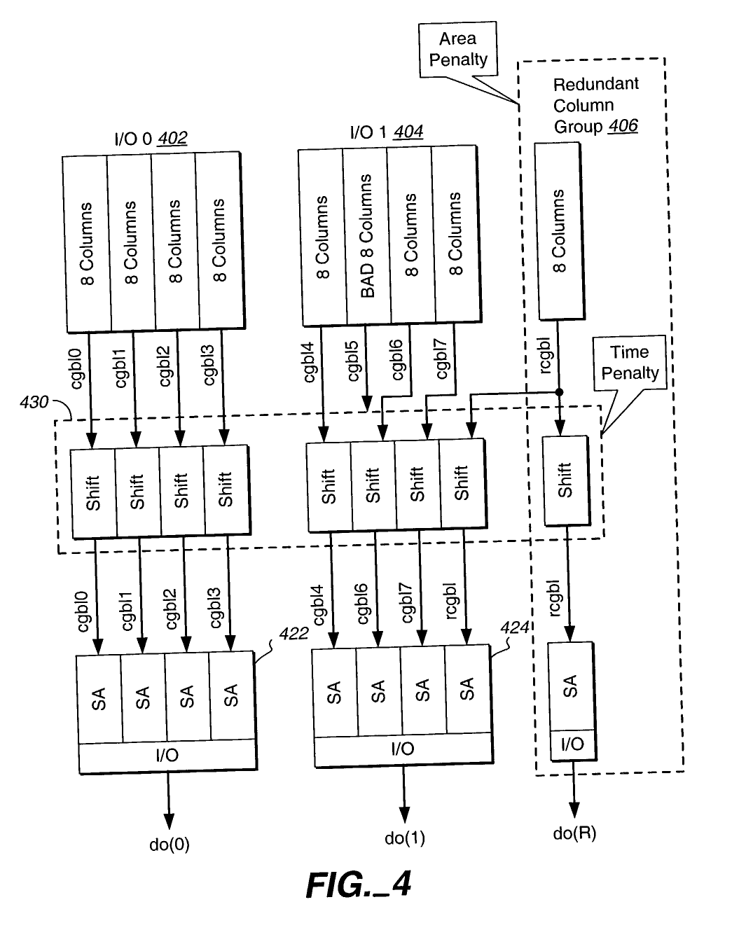

Turning now to FIG. 4, a diagram is shown illustrating an example column group repair by shifting out a bad column group in accordance with a preferred embodiment of the present invention. I/O 0 402, I/O 1 404, and redundant column group 406 are shown. The memory also includes shifting stage 430 including a shift circuit for each column group. In the example shown in FIG. 4, the memory is tested and a bad column group is identified in I/O 1 404, the bad column group having column group bitlines cgbl5. The shift circuits for cgbl5 and the column group bitlines after the bad column group are activated. Thus, cgbl0, cgbl1, cgbl2, cgbl3, and cgbl4 are allowed to pass through the shifting stage; however, cgbl5 are shifted out and cgbl6 are shifted into their place. Similarly, cgbl7 are shifted into the place of cgbl6 and the redundant column group bitlines, rcgbl, are shifted into the place of cgbl7.

In a third stage, each pair of shifted column group bitlines is fed into a sense amplifier and the four sense amplifier outputs for each I/O are then multiplexed into a I/O. In the example shown in FIG. 4, the shifted column group bitlines for I/O 0 are cgbl0, cgbl1, cgbl2, and cgbl3. These column group bitlines are fed into sense amplifiers 422 and the outputs of sense amplifiers 422 are multiplexed into data output do(0). However, the shifted column group bitlines for I/O 1 are cgbl4, cgbl6, cgbl7, and rcgbl. These column group bitlines are fed into sense amplifiers 424 and the outputs of sense amplifiers 424 are multiplexed into data output do(1).

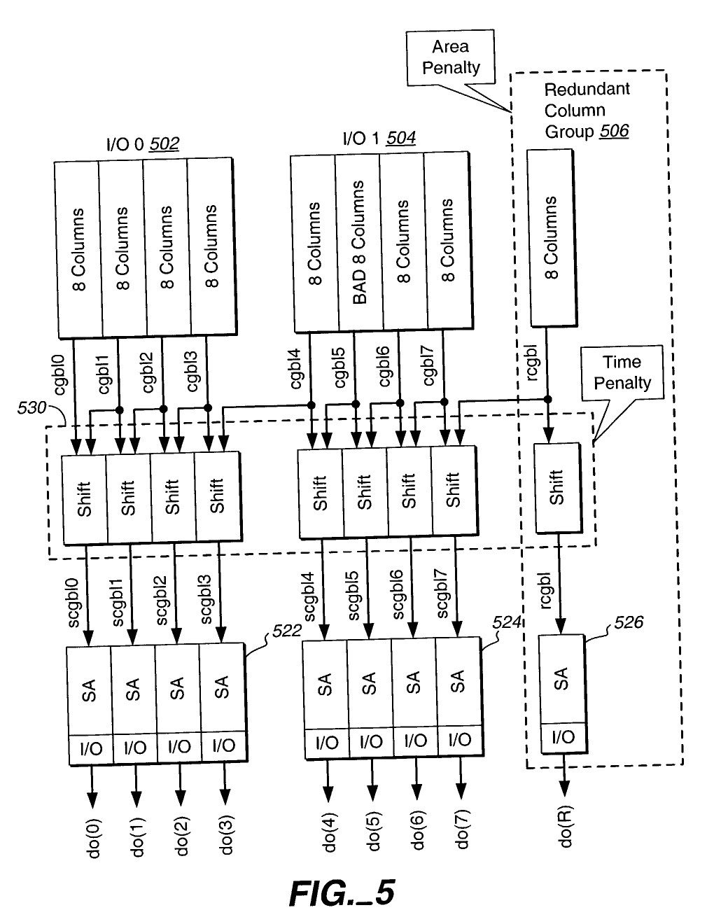

With reference now to FIG. 5, an example diagram illustrating a column shifting column group repair scheme with 8:1 MUX is shown in accordance with a preferred embodiment of the present invention. The memory circuit includes a plurality (N+1) of groups of thirty-two columns. I/O 0 502 and I/O 1 504 are shown. For simplicity, only two I/Os are shown and the columns are divided into groups of eight columns. However, the memory may include more or fewer I/Os and may divide the columns into more or fewer columns depending upon the implementation.

In this example, the first stage has eight single columns with eight pairs of bitlines multiplexed into one column group with one pair of column group bitlines. For example, I/O 0 502 has four groups of eight columns multiplexed into column group bitlines cgbl0, cgbl1, cgbl2, cgbl3. Similarly, I/O 1 504 has four groups of eight columns multiplexed into column group bitlines cgbl4, cgbl5, cgbl6, cgbl7. The memory also includes redundant column group 506, which is one group of eight columns multiplexed into redundant column group bitlines rcgbl.

In accordance with a preferred embodiment of the present invention, the memory includes shifting stage 530 including a shift circuit for each column group. Each pair of column group bitlines is fed into a shift circuit for the column group and a shift circuit for an adjacent column group. When the memory is tested and a bad column group is identified, the shift circuits for the bad column group and each column group after the bad column group are activated. Thus, the bad column group is shifted out and redundant column group 506 is shifted in at the end.

In a third stage, each pair of shifted column group bitlines is fed into a sense amplifier and each sense amplifier output is then provided as an I/O. In the example shown in FIG. 5, the shifted column group bitlines for I/O 0 are fed into sense amplifiers 522 and the outputs of sense amplifiers 522 are provided as data outputs do(0), do(1), do(2), and do(3). Similarly, the shifted column group bitlines for I/O 1 are fed into sense amplifiers 524 and the outputs of sense amplifiers 524 are provided as data outputs do(4), do(5), do(6), and do(7). The redundant column group bitlines from the shifting stage may also be fed into sense amplifier 526 and accessed as do(R).

The examples shown in FIGS. 3-5 are not meant to imply architectural limitations. For instance, the number of columns per group, the number of columns per I/O, the number of levels of multiplexing, and the ratio at which the columns are multiplexed may vary depending upon the implementation. Furthermore, the number of redundant columns may also vary. For example, the column group repair scheme may include two redundant column groups within the scope of the invention. The testing and repair may be performed after fabrication, such as by burning a fuse. Alternatively, the column groups may be tested and control signals may be set for the shift circuits at system start-up. In addition, the memory circuits are shown with arrows showing data outputs. However, memory access may take the form of input and output. Since the shift circuits are set and remain set as long as the memory is in use, data may be read from and written to the columns without risk of corruption.

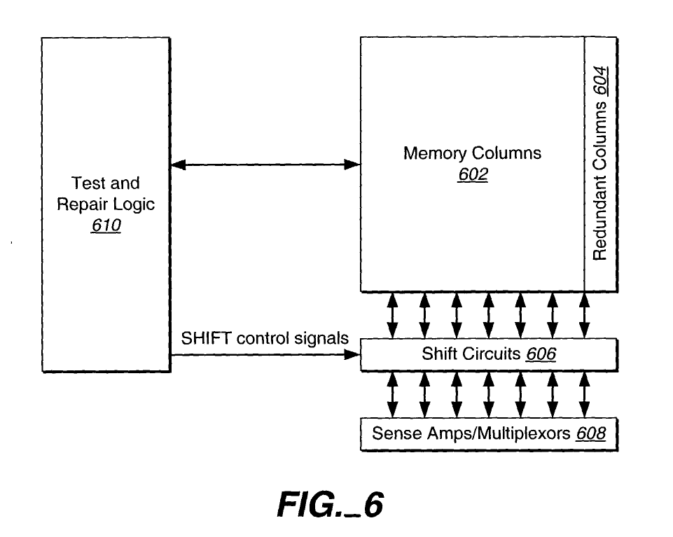

With reference to FIG. 6, a block diagram illustrating a memory with column shifting column group repair is depicted in accordance with a preferred embodiment of the present invention. The memory includes memory columns 602 and redundant columns 604. Shift circuits 606 are selectively activated to shift out bad columns from memory columns 602 and redundant columns 604 are shifted in to fill the void. The memory also includes sense amplifiers and/or multiplexors 608 to provide access to the appropriate number of I/Os.

In accordance with a preferred embodiment of the present invention, the memory includes test and repair logic 610. Techniques for testing for bad columns are known in the art and are not the focus of the present invention. Test and repair logic 610 identifies a bad column group and sets the appropriate SHIFT control signals for shift circuits 606.

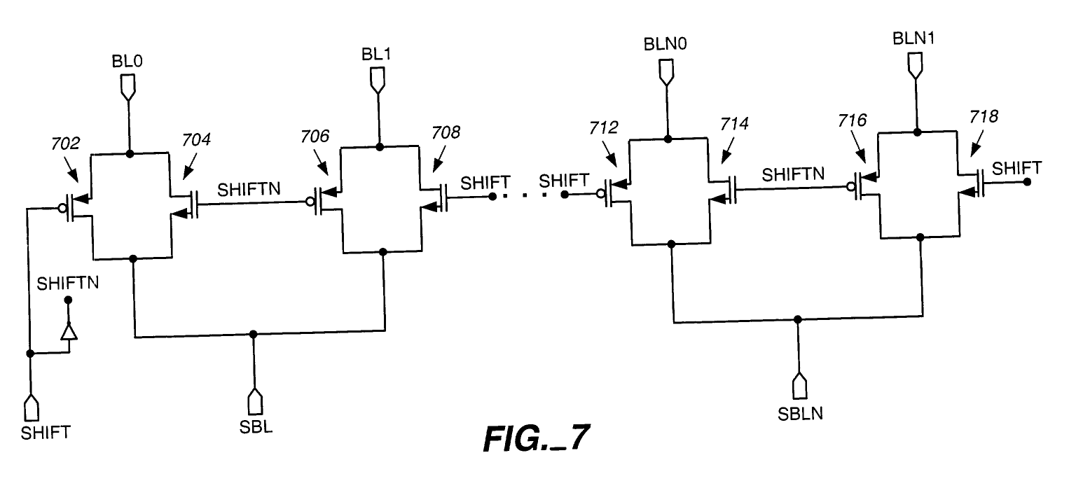

Next, with reference to FIG. 7, a circuit diagram of an example shift circuit is shown in accordance with a preferred embodiment of the present invention. Each shift circuit receives a shift control signal (SHIFT), a first pair of bitlines (BL0, BLN0), and a second pair of bitlines (BL1, BLN1). The shift circuit includes four pairs of transistors. Transistors 702, 706, 712, 716 are positive-channel metal oxide semiconductor (PMOS) transistors. Transistors 704, 708, 714, 718 are N-channel metal oxide semiconductor (NMOS) transistors. If SHIFT is deasserted (low), then transistors 702, 704, 712, 714 allow current to flow from bitlines BL0, BLN0 to the shifted bitlines SBL, SBLN. Thus, BL0, BLN0 may be set to the column group bitlines for the shift circuit.

Alternatively, if SHIFT is asserted (high), then transistors 706, 708, 716, 718 allow current to flow from bitlines BL1, BLN1 to shifted bitlines SBL, SBLN. Thus, BL1, BLN1 may be set to the column group bitlines adjacent to the column group to which the shift circuit corresponds.

The shift circuit shown in FIG. 7 is intended as an example and is not meant to imply architectural limitations. Other components and configurations may be used to achieve the same or similar function. A shift circuit, as shown in FIG. 7, may be included for each column group in the memory; however, other arrangements of shift circuits may be used at various levels of multiplexing or with a variety of column groupings.

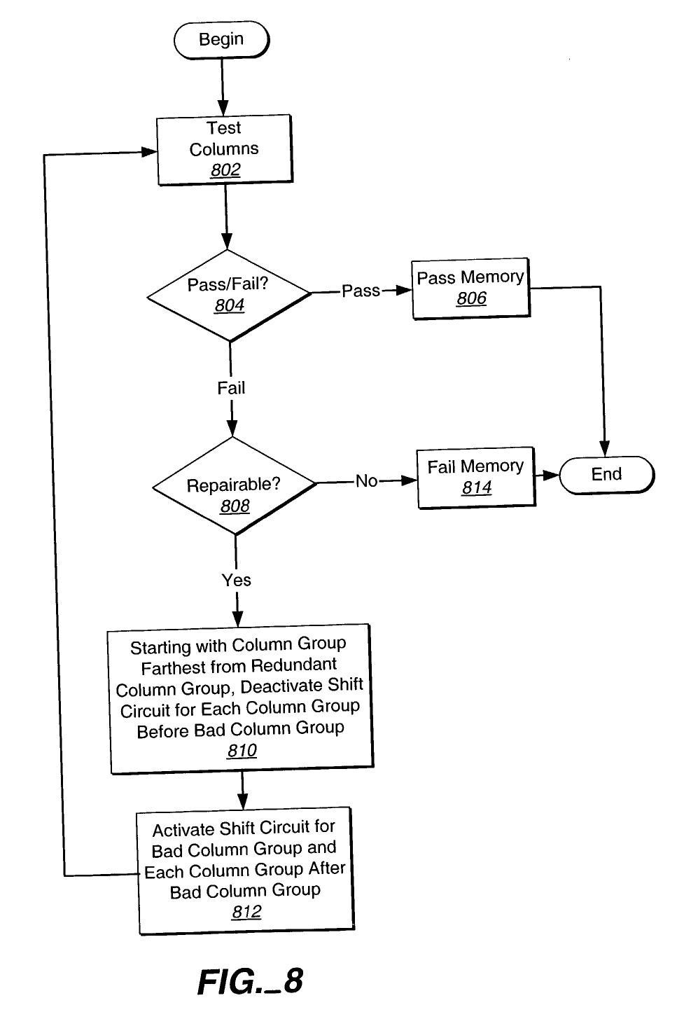

With reference now to FIG. 8, a flowchart of the operation of a column shifting repair scheme is illustrated in accordance with a preferred operation of the present invention. The process begins and tests the memory columns (step 802). Next, a determination is made as to whether the memory passes or fails the test (step 804). If the memory passes the test, the process passes the memory (step 806) and ends.

If the memory fails the test in step 804, a determination is made as to whether the memory is repairable (step 808). If the memory is repairable in step 808, the process deactivates the shift circuits for each column group before the bad column group, starting with the column group farthest from the redundant column group (step 810). Then, the process activates the shift circuit for the bad column group and each column group after the bad column group (812). Thereafter, the process returns to step 802 to retest the columns. If the memory is not repairable in step 808, the process fails the memory (step 814) and ends.

Thus, the present invention solves the disadvantages of the prior art by providing a column group repair scheme that includes a shifting stage. A plurality of shift circuits are selectively activated to shift out a bad column group. A redundant column group is provided to fill the void. Thus, the column group repair scheme of the present invention is more simple to implement than the single column repair scheme and has a smaller area and performance penalty than the I/O repair scheme.

What is claimed is:

1. A method for repairing a bad column group in a memory, comprising:
identifying a first column group as a bad column group;
selectively activating a first shift circuit to shift out the first column group; and
shifting in a redundant column group.

2. The method of claim 1, wherein the step of shifting in a redundant column group includes:
activating the first shift circuit to shift in the redundant column group in place of the first column group.

3. The method of claim 1, wherein the step of shifting in a redundant column group includes:
activating the first shift circuit to shift in a second column group in place of the first column group.

4. The method of claim 1, wherein the step of shifting in a redundant column group includes:
selectively activating each shift circuit between the bad column group and the redundant column group.

5. The method of claim 4, wherein the step of selectively activating each shift circuit between the bad column group and the redundant column group includes generating a shift signal for each shift circuit between the bad column group and the redundant column.

6. The method of claim 4, wherein the step of selectively activating each shift circuit between the bad column group and the redundant column group includes burning a fuse for each shift circuit between the bad column group and the redundant column, wherein burning a fuse generates a shift signal.

7. A method for repairing bad columns in a memory, comprising:
performing a test on columns in the memory, wherein the memory includes a plurality of column groups and at least one redundant column group;
responsive to the memory failing the test, determining whether the memory is repairable; and
responsive to the memory being repairable, deactivating a shift circuit for each column group before a bad column group starting with a column group farthest from the at least one redundant column group and activating a shift circuit for the bad column group and each column group after the bad column group.

8. The method of claim 7, wherein the step of determining whether the memory is repairable includes determining whether a number of bad column groups is less than or equal to a number of the at least one redundant column groups.

9. The method of claim 7, wherein the steps of deactivating a shift circuit for each column group before a bad column group and activating a shift circuit for the bad column group and each column group after the bad column group form a repaired memory, the method further comprising:
performing the test on columns in the repaired memory.

10. A memory, comprising:
a plurality of column groups;
a redundant column group;
a plurality of shift circuits, wherein each shift circuit corresponds to a column group; and
a test and repair logic that identifies a bad column group from the plurality of column groups, selectively activates a first shift circuit from the plurality of shift circuits to shift out the bad column group, and shifts in a redundant column group.

11. The memory of claim 10, wherein the test and repair logic activates the first shift circuit to shift in the redundant column group in place of the bad column group.

12. The memory of claim 10, wherein the test and repair logic activates the first shift circuit to shift in an adjacent column group from the plurality of column groups in place of the bad column group.

13. The memory of claim 10, wherein the test and repair logic selectively activates each shift circuit between the bad column group and the redundant column group.

14. The memory of claim 10, wherein the test and repair logic generates a shift signal for each shift circuit between the bad column group and the redundant column.

15. The memory of claim 10, wherein the test and repair logic bums a fuse for each shift circuit between the bad column group and the redundant column, wherein a burned fuse results in a shift signal being generated.

16. The memory of claim 10, wherein each shift circuit includes a first pair of switches coupled to a first pair of column group bitlines and a second pair of switches connected to a second pair of column group bitlines.

17. The memory of claim 16, wherein the first pair of switches and the second pair of switches receive a shift signal.

18. The memory of claim 17, wherein the first pair of switches outputs the first pair of column group bitlines if the shift signal is not present.

19. The memory of claim 17, wherein the second pair of switches outputs the second pair of column group bitlines if the shift signal is present.

20. An apparatus for repairing bad columns in a memory, comprising:
test means for performing a test on columns in the memory, wherein the memory includes a plurality of column groups and at least one redundant column group;
determination means, responsive to the memory failing the test, for determining whether the memory is repairable; and
repair means for deactivating a shift circuit for each column group before a bad column group starting with a column group farthest from the at least one redundant column group and activating a shift circuit for the bad column group and each column group after the bad column group, responsive to the memory being repairable.

21. The apparatus of claim 20, wherein the determination means includes means for determining whether a number of bad column groups is less than or equal to a number of the at least one redundant column groups.

22. The apparatus of claim 20, wherein the repair means forms a repaired memory, the apparatus further comprising:
means for performing the test on columns in the repaired memory.
